(19) United States
(12) Patent Application Publication
(10) Pub. No.: US 2006/0081869 A1
(43) Pub. Date: Apr. 20, 2006

(54) Flip-chip electrode light-emitting element formed by multilayer coatings

(76) Inventors: Chi-Wei Lu, Dashi (TW); Wen-Chieh Huang, Dashi (TW); Pan-Tzu Chang, Dashi (TW); James Wang, Dashi (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 11/242,035

(22) Filed: Oct. 4, 2005

(30) Foreign Application Priority Data
Oct. 20, 2004 (TW) 093131772

(51) Int. Cl. H01L 33/00

(52) U.S. Cl. 257/99

(57) ABSTRACT

A flip-chip electrode light-emitting element formed by multilayer coatings where a translucent conducting layer and a highly reflective metal layer acts as flip-chip electrode for enhancing the LED luminous efficiency. The flip-chip electrode light-emitting element includes a translucent substrate, a semiconductor die structure attached on the translucent substrate and made of group III nitride compounds, and an intermediate layer adapted to support the inverted semiconductor die structure on a submount. The flip-chip electrode formed by multiplayer coatings includes a current-spreading transparent conducting layer formed on a top side of the second type semiconductor layer, a highly reflective metal layer formed on a top side of the transparent conducting layer, a metallic diffusion barrier layer formed on a top side of the highly reflective metal layer, and a bonding layer electrically coupled to the intermediate layer and formed on a top side of the barrier layer. Moreover, an ohmic contact layer is formed on the transparent conducting layer. And a passivation layer encloses the die structure for insulating p/n interface and for avoiding the creation of the leakage current.

### BACKGROUND OF THE INVENTION

1. Field of the Invention

The invention relates to a flip-chip light-emitting diode (LED), and more particularly to a flip-chip electrode light-emitting element formed by multiplayer coatings for enhancing the current spreading function and for reflecting the light beam in the direction of the electrode to a translucent substrate. In this way, the luminous efficiency can be increased.

2. Description of the Related Art

The lattice match is a significant task for the semiconductor LED. For the most of the III-V compound semiconductor, a good substrate for supporting an epitaxy layer is still unavailable. The lattice of the grew epitaxy layer has to match to that of the substrate for preventing photons from being absorbed by defective portions of the lattice damaged by the stress in the process. Otherwise, the luminous efficiency of the light-emitting diode would be considerably lowered.

In addition, blue/green LEDs were made of ZnSe and GaN in the early stage. ZnSe has problem in reliability so that GaN gained a good chance for further development. However, the research on GaN was not evidently developed because a good substrate matching to the GaN lattice constant is not available so that the defect density of the epitaxy still remains high. Consequently, the luminous efficiency cannot be improved. The epitaxy technique didn't gain a significant breakthrough until S. Yoshida, etc. grew GaN on a sapphire substrate in the year of 1983.

The GaN-based sapphire substrate requires an n-type and a p-type electrode that are located on the same side. With the conventional packaging method, light emitted from active layer at most of the view angle will be blocked by the electrode. This leads to low luminous intensity of the LED.

The so-called flip chip mounting, as shown in FIG. 1, means that a conventional light-emitting element 10 is mounted on a heat-conducting substrate 20 in an inverted manner. A highly reflective layer is disposed on a top of a p-type electrode 11. The light beam that is originally emitted vertically and blocked by the electrodes can now be borught out from other view angle. Accordingly, the light can be extracted from the rim of the sapphire substrate 12. This design can reduce the light loss due to the above-mentioned reasons. It improves the luminous efficiency about twice while comparing with the packaging result from the conventional packaging method.

Such a flip-chip LED has been disclosed by the inventor of the present invention and titled as “LED configuration for a high luminance”. In addition, U.S. Pat. No. 4,476,620 discloses a “Method of making a gallium nitride light-emitting diode”. Moreover, such a flip-chip LED has been disclosed also in JP 2001-170909 and titled as “semiconductor light-emitting element made of III-group nitride compound”. TW 461123 also describes a “Method and structure of flip chip mounting for LEDs”. And what is more, TW 543128 discloses a “light-emitting semiconductor with surface adhesion and with a flip chip packaging structure”.

In the aforementioned prior arts, the flip-chip LED aims at the manufacture of a reflection layer at a top of p-type electrode so that the light beam can be effectively reflected and transmitted via a translucent substrate thereabove. Furthermore, the surface of the substrates is roughened for enhancing the light extraction efficiency. These methods have been familiar to the LED industry. However, how to fabricate a flip chip electrode with high reflection and current spreading function requires further breakthrough. It is because those material used for making the electrodes has very different characteristics. Some materials will result in inter-diffusion that reduces reflection. Some other materials have excellent reflection effect, but with high ohmic contact resistance that leads to a bad current spreading. These will all affect the luminous efficiency of flip chip LED.

Accordingly, the invention is aimed at a further improvement on this topic for an effective breakthrough of the problem caused by the conventional flip-chip electrode.

### SUMMARY OF THE INVENTION

A primary object of the invention is to provide a flip-chip electrode of multiplayer coatings on an LED die wherein these multiplayer coatings supplement each other for current spreading and high reflective function. In this way, the luminous efficiency can be upgraded.

Another object of the invention is to provide a flip-chip LED with a high reliability and stability.

In order to reach the above-mentioned objects, the invention includes:

a) a translucent substrate;

b) a semiconductor die structure attached on the translucent substrate and made of group III nitride compound, the semiconductor die structure includes:
i) a first type semiconductor layer formed on a top side of the translucent substrate;
ii) a first electrode formed on a partial surface of the first type semiconductor layer;
iii) an active layer formed on a top side of the first type semiconductor layer without covering the first electrode;
iv) a second type semiconductor layer formed on a top side of the active layer; and
v) a second electrode formed on a top side of the second type semiconductor layer;

c) a submount having formed thereon at least two traces corresponding to the first and the second electrode, respectively; and

d) at least one intermediate layer adapted to support the inverted semiconductor die structure on the traces of the submount, wherein the second electrode formed by multilayer coatings includes:

a transparent conducting layer for spreading the electrical current, the transparent conducting layer being formed on a top side of the second type semiconductor layer;

a highly reflective metal layer formed on a top side of the transparent conducting layer;

a barrier layer for preventing the metallic diffusion, the barrier layer being formed on a top side of the highly reflective metal layer; and

a bonding layer electrically coupled to the intermediate layer, the bonding layer being formed on a top side of the barrier layer.

The above-mentioned configuration can further comprises an ohmic contact layer formed on the transparent conducting layer and a passivation layer enclosing the die structure for insulating p/n-type interface and for avoiding the creation of the leakage current.

### BRIEF DESCRIPTION OF THE FIGURES

The accomplishment of this and other objects of the invention will become apparent from the following descriptions and its accompanying figures of which:

FIG. 1 is a schematic drawing of the structure of a conventional flip-chip LED;

FIG. 2 is a schematic drawing of a first embodiment of a die structure of the invention;

FIG. 3 is a schematic drawing of the first embodiment of the die structure of the invention attached to a submount in a flip chip mounting manner;

FIG. 4 is a schematic drawing of a second embodiment of a die structure of the invention;

FIG. 5 is a schematic drawing of the second embodiment of the die structure of the invention attached to a submount in a flip chip mounting manner;

FIG. 6 is a schematic drawing of a third embodiment of the die structure of the invention attached to a submount in a flip chip mounting manner;

FIG. 7 is a schematic drawing of an ohmic contact layer of the third embodiment of the die structure of the invention attached to a submount in a flip chip mounting manner; and

FIG. 8 is a cutaway view taken along lines 8-8 of FIG. 7.

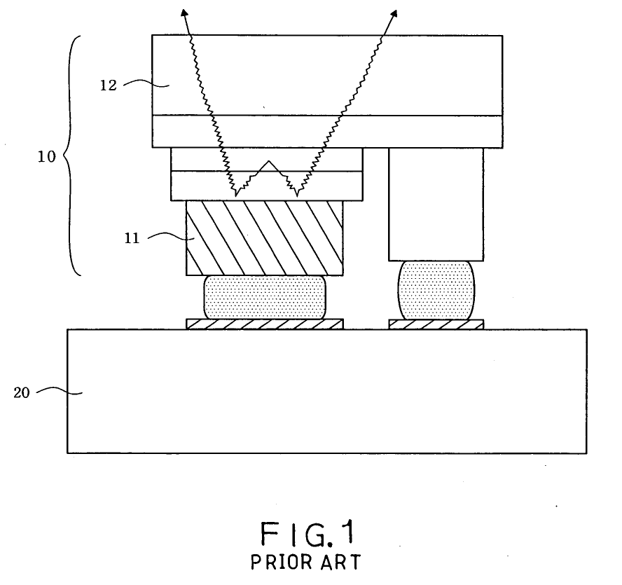

### DETAILED DESCRIPTION OF THE PREFERRED EMBODIMENT

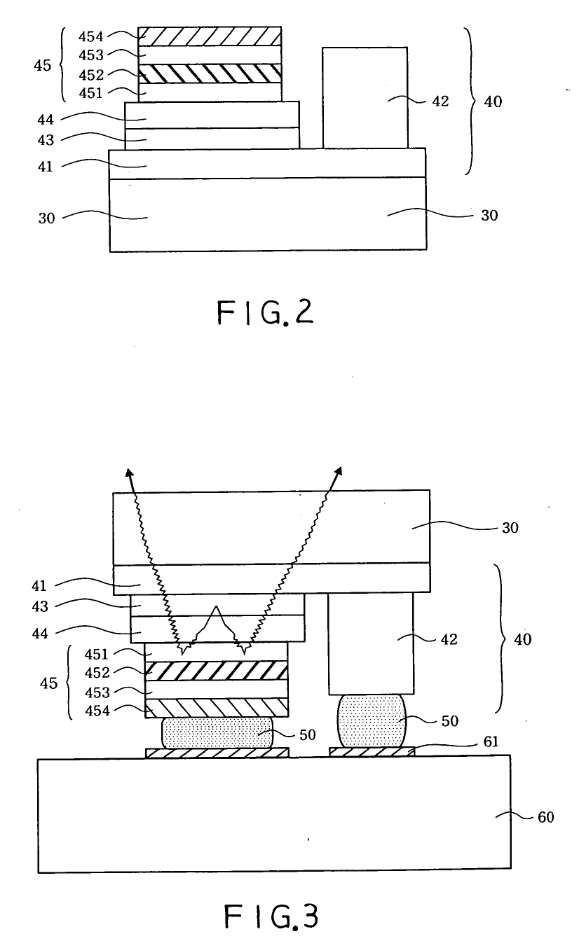

First of all, referring to FIG. 2, an embodiment of a light-emitting diode (LED) die includes a translucent substrate 30 and a semiconductor die structure 40.

In accordance with the invention, the translucent substrate 30 is preferably a sapphire substrate.

The semiconductor die structure 40 is attached on the translucent substrate 30 and made of group III nitride compound. The semiconductor die structure 40 includes a first type semiconductor layer 41 (e.g. n-type gallium nitride) formed on a top side of the translucent substrate 30. A first electrode 42 is formed on a top side of the first type semiconductor layer 41 acting as n-type gallium nitride. The first electrode 42 functions as n-electrode. An active layer 43 beside the first electrode 42 is formed on a top side of the first type semiconductor layer 41 without covering the first electrode 42. A second type semiconductor layer 44 acts as p-type gallium nitride and is formed on a top side of the active layer 43. A second electrode 45 is formed on a top side of the second type semiconductor layer 44 made of the p-type gallium nitride. The second electrode 45 functions as p-type electrode. Therefore, the above-mentioned structure creates a quaternary AlInGaN-based LED. The first type semiconductor layer 41 can, of course, act as p-type gallium nitride while the second type semiconductor layer 44 functions, to the contrary, as n-type gallium nitride. This belongs to the prior art so that no further descriptions thereto are given hereinafter.

As shown in FIG. 3, the semiconductor die structure 40 formed in the aforementioned way is attached to a submount 60 in a flip chip manner. The submount 60 functions as a substrate with high coefficient of heat conductivity, such as an n-type or a p-type silicon substrate. Of course, the submount 60 can be replaced by a ceramic substrate. At least two traces 61 corresponding to the first and the second electrode 42, 45 are disposed on the submount 60. Meanwhile, two intermediate layers 50 are interposed between the electrodes 42, 45 and the traces 61, respectively. In this way, the semiconductor die structure 40 is mounted on the submount 60 to form a flip chip light-emitting diode. The distribution and the area of the traces 61, like that the traces 61 is extended in direction to both sides of the submount 60, or the submount 60 requires an insulating layer formed on the surface thereof, belong to the prior art so that no further descriptions are given hereinafter. The invention features that the second electrode 45 acting as p-type electrode consists of multilayer coatings. In other words, the second electrode 45 includes a transparent conducting layer 451, a highly reflective metal layer 452, a barrier layer 453 and a bonding layer 454.

The transparent conducting layer 451 for distributing electric current is formed on a top side of the second type semiconductor layer 44 and selected from a group that consists of indium tin oxide (ITO), ZnO and AlGaInSnO. The transparent conducting layer 451 provides an ohmic contact to the second type semiconductor and has the function of current spreading and the translucent property.

The highly reflective metal layer 452 is formed on a top side of the transparent conducting layer 451. The material of the highly reflective metal layer 452 is selected from a group consisting of aluminum (Al), silver (Ag), palladium (Pd), platinum (Pt), ruthenium (Ru), and rhodium (Rh). The second electrode 45 acting as flip chip must permit the excellent current spreading and the high reflection performance. So, the excellent current spreading is achieved by the transparent conducting layer 451 while aluminum (Al), silver (Ag), etc. function as the highly reflective metal. However, the aluminum (Al) and the gold (Au) have a potential risk to diffuse to each other under the high temperature condition and this will result in a negative influence on the reflection effect of the aluminum (Al). So, a barrier layer 453 is formed on a top side of the highly reflective metal layer 452 to prevent metal from diffusing to each other. The barrier layer 453 is selected from a group consisting of titan (Ti), platinum (Pt), tungsten (W), titan-tungsten-alloy (TiW) and nickel (Ni). These are not only used to prevent diffusion, but also serve as excellent reflective metal.

Finally, a bonding layer 454 electrically coupled to the intermediate layer 50 is formed on a top side of the barrier layer 453. The material is selected from a group consisting of gold (Au) and tin (Sn). The barrier layer 453 is formed between the highly reflective metal layer 452 and the bonding layer 454. This will prevent gold from diffusing into aluminum. By this way, a highly reflective metal layer 452 can be manufactured. Moreover, the bonding layer 454 has an excellent solderability. The barrier layer 453 can prevent the soldering agent from spreading into the second electrode 45 to deteriorate the elements. The material of the intermediate layers 50 is selected from a group consisting of base metal, metal alloy, semiconductor alloy, thermally and electrically conductive adhesive, congruently melting joint between the LED die and the submount, gold (Au) stud bump, and solder bump.

The flip-chip second electrode 45 consisting of the transparent conducting layer 451, the highly reflective metal layer 452, the barrier layer 453 and the bonding layer 454 covers the most part of the surface of the second type semiconductor layer 44. Since the second electrode 45 is not limited to certain dimensions and thickness, the structure of the second electrode 45 can be designed to optimize the current spreading effect. Besides, all of the metal coating layers feature the high reflective performance. So, the light beam emitted by the active layer 43 in the direction of the second electrode 45 can be reflected in the direction of the translucent substrate 30, thereby enhancing the luminous efficiency. Furthermore, the electrode of the multiplayer coatings permits the stability of the semiconductor die structure 40.

The semiconductor die structure 40 in accordance with the invention is attached to the submount 60 via the intermediate layers 50 in a flip chip mounting manner. The heat created during the lighting-up process of the semiconductor die structure 40 can be rapidly transmitted to the outside of the elements via the submount 60. So, the semiconductor die structure 40 is suitable for high power light-emitting diodes.

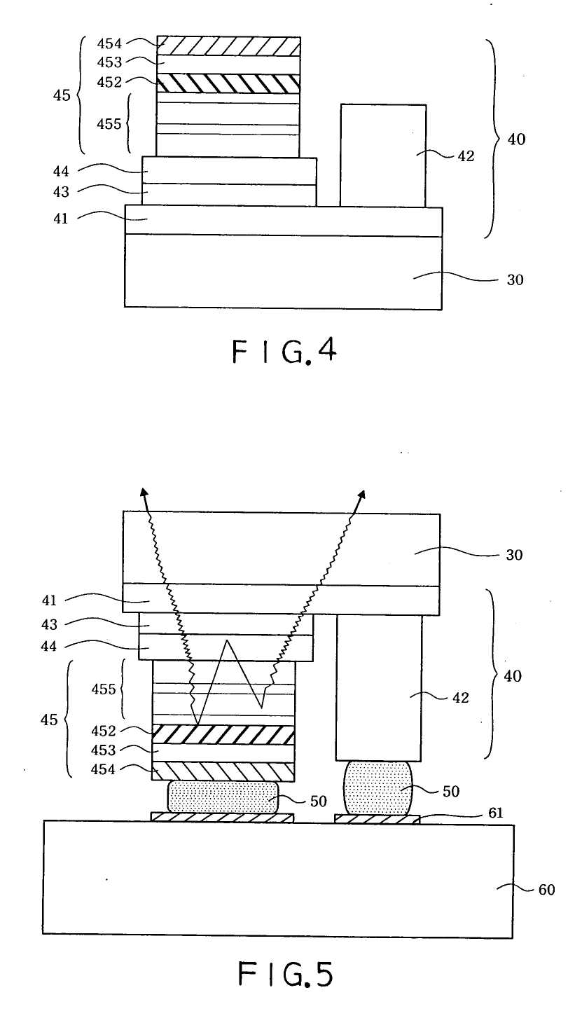

FIGS. 4 and 5 show another embodiment of the invention. This embodiment is substantially identical to the aforementioned embodiment. In other words, it relates to a flip chip electrode providing a current spreading function and having a highly reflective metal layer. The difference between both embodiments lies in that the transparent conducting layer 455 of the second type semiconductor GaN-layer 44 acts as transparent conducting oxide (TCO). The transparent conducting oxide (TCO) in accordance with this embodiment can relate to TCO described in a pending patent of the inventor where an Al₂O₃—Ga₂O₃—In₃O₃—SnO₂-system is disclosed. The TCO includes an amorphous or a nanocrystalline film having a better electrical conductivity. Meanwhile, the TCO film has the conductivity ten times as much as the aforementioned ITO layer. The transparent conducting layer 455 that functions as distributed Bragg reflector (DBR) cooperates with the highly reflective metal layer 452 to allow for a much better reflective effect. In this way, the luminous efficiency of the semiconductor die structure 40 in the direction of the translucent substrate 30 can be increased. DBR technique belongs to the prior art in the semiconductor manufacturing field so that no further descriptions thereto are given hereinafter.

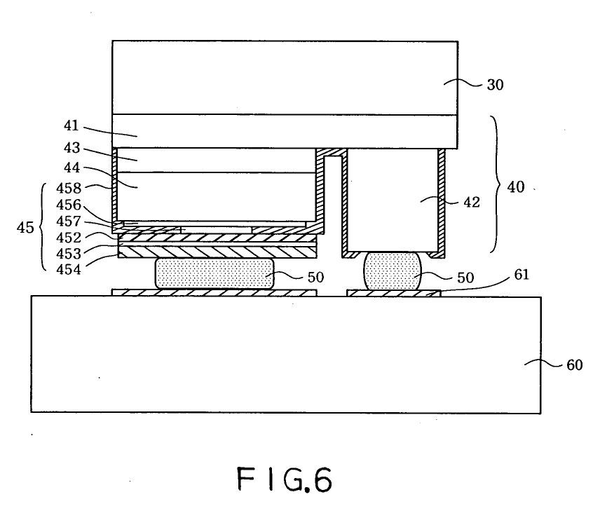

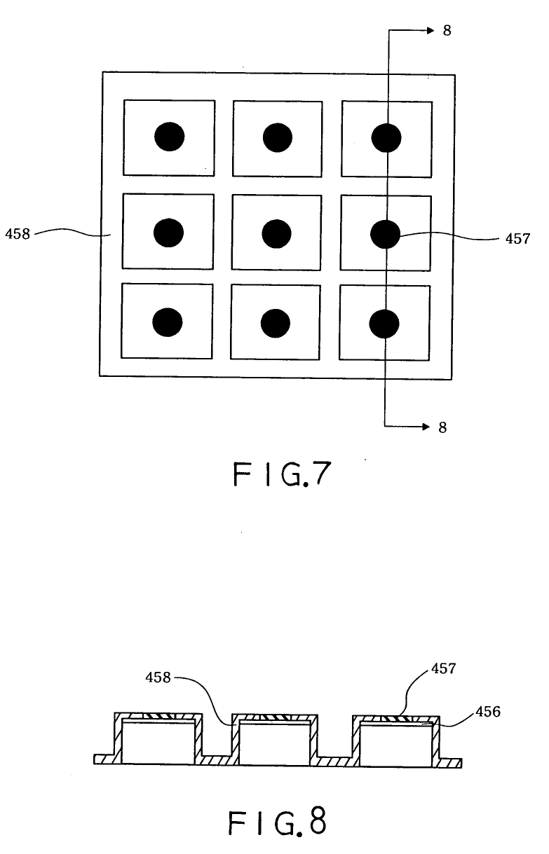

FIG. 6 illustrates a further embodiment of the invention. The embodiment in accordance with FIG. 6 is substantially identical to the aforementioned embodiments. The difference between them lies in that an ohmic contact layer 457 is formed on a partial surface of the transparent conducting layer 456 of the second type semiconductor GaN-layer 44. Meanwhile, a passivation layer 458 encloses the semiconductor die structure 40 and a partial surface of the first electrode 42. In addition, the passivation layer 458 doesn't cover the surface of the ohmic contact layer 457. Otherwise, the other components are the same to that of the previously described embodiments. In other words, the high reflective metal layer 452 is adhered to the surface of the ohmic contact layer 457, and the barrier layer 453 is formed on the surface of the highly reflective metal layer 452. In addition, the bonding layer 454 is formed on the surface of the barrier layer 453. The passivation layer 458 is used to avoid the disadvantages caused by the flip chip packaging. The disadvantages include an excessive leakage current of the surface of the element, a short circuit of the electrode and a bad positioning. As shown in FIGS. 7 and 8, the passivation layer 458 has an evenly distributed configuration in a projecting manner for facilitating the even distribution of the electric current and for enhancing the effect of the highly reflective metal layer 452 closely coupled thereto. In this way, the conductivity and translucency of the light-emitting element can be maximized to enhance the light extraction efficiency thereof.

The structure in accordance with the invention differs from that of the prior art in that the multiplayer coatings of the flip chip electrode can effectively achieve the excellent current spreading and the high reflective effect. So, the light beam in direction of the electrode can be reflected to the translucent substrate for enhancing the light-emitting efficiency.

Many changes and modifications in the above-described embodiments of the invention can, of course, be carried out without departing from the scope thereof. Accordingly, to promote the progress in science and the useful arts, the invention is disclosed and is intended to be limited only by the scope of the appended claims.

What is claimed is:

1. A flip-chip electrode light-emitting element formed by multilayer coatings, comprising:
a) a translucent substrate;
b) a semiconductor die structure attached on the translucent substrate and made of group III nitride compounds, the semiconductor die structure includes:
i) a first type semiconductor layer formed on a top side of the translucent substrate;
ii) a first electrode formed on a partial surface of the first type semiconductor layer;
iii) an active layer formed on a top side of the first type semiconductor layer without covering the first electrode;
iv) a second type semiconductor layer formed on a top side of the active layer; and
v) a second electrode formed on a top side of the second type semiconductor layer;
c) a submount having formed thereon at least two traces corresponding to the first and the second electrode, respectively; and
d) at least one intermediate layer adapted to support the semiconductor die structure in a flip chip mounting manner on the traces of the submount, wherein the second electrode formed by multilayer coatings includes:
a transparent conducting layer for spreading electrical current, the transparent conducting layer being formed on a top side of the second type semiconductor layer;
a highly reflective metal layer formed on a top side of the transparent conducting layer;
a barrier layer for preventing the metallic diffusion, the barrier layer being formed on a top side of the high reflective metal layer; and
a bonding layer electrically coupled to the intermediate layer, the bonding layer being formed on a top side of the barrier layer.

2. The flip-chip electrode light-emitting element formed by multilayer coatings as recited in claim 1 wherein the transparent conducting layer is selected from a group consisting of an indium tin oxide (ITO) layer, a zinc oxide (ZnO) layer, an AlGaInSnO layer, and a distributed Bragg reflector (DBR) made of transparent conductive oxide.

3. The flip-chip electrode light-emitting element formed by multilayer coatings as recited in claim 1 wherein the material of the highly reflective metal layer is selected from a group consisting of aluminum (Al), silver (Ag), palladium (Pd), platinum (Pt), ruthenium (Ru), and rhodium (Rh).

4. The flip-chip electrode light-emitting element formed by multilayer coatings as recited in claim 1 wherein the material of the barrier layer is selected from a group consisting of titan (Ti), platinum (Pt), tungsten (W), titan-tungsten-alloy (TiW) and nickel (Ni).

5. The flip-chip electrode light-emitting element formed by multilayer coatings as recited in claim 1 wherein the material of the bonding layer is selected from a group consisting of gold (Au) and tin (Sn).

6. The flip-chip electrode light-emitting element formed by multilayer coatings as recited in claim 1 wherein the material of the intermediate layer is selected from a group consisting of base metal, metal alloy, semiconductor alloy, thermally and electrically conductive adhesive, congruently melting joint between the LED die and the submount, gold (Au) stud bump, and solder bump.

7. The flip-chip electrode light-emitting element formed by multilayer coatings as recited in claim 1 wherein the first and the second type semiconductor layers are made of quaternary AlInGaN material.

8. The flip-chip electrode light-emitting element formed by multilayer coatings as recited in claim 7 wherein the first and the second type semiconductor layer are constructed as an n-type and a p-type gallium nitride (GaN) layer, respectively.

9. The flip-chip electrode light-emitting element formed by multilayer coatings as recited in claim 7 wherein the first and the second type semiconductor layer are constructed as a p-type and an n-type gallium nitride (GaN) layer, respectively.

10. The flip-chip electrode light-emitting element formed by multilayer coatings as recited in claim 1 wherein the submount includes a substrate with high coefficient of heat conductivity.

11. The flip-chip electrode light-emitting element formed by multilayer coatings as recited in claim 10 wherein the submount includes an n-type silicon (Si) substrate.

12. The flip-chip electrode light-emitting element formed by multilayer coatings as recited in claim 10 wherein the submount includes a p-type silicon (Si) substrate.

13. The flip-chip electrode light-emitting element formed by multilayer coatings as recited in claim 1 wherein the submount includes a ceramic substrate.

14. The flip-chip electrode light-emitting element formed by multilayer coatings as recited in claim 1 wherein the translucent substrate 30 includes a sapphire substrate.

15. A flip-chip electrode light-emitting element formed by multilayer coatings, comprising:
a) a translucent substrate;
b) a semiconductor die structure attached on the translucent substrate and made of group III nitride compounds, the semiconductor die structure includes:
i) a first type semiconductor layer formed on a top side of the translucent substrate;
ii) a first electrode formed on a partial surface of the first type semiconductor layer;
iii) an active layer formed on a top side of the first type semiconductor layer without covering the first electrode;
iv) a second type semiconductor layer formed on a top side of the active layer; and
v) a second electrode formed on a top side of the second type semiconductor layer;
c) a submount having formed thereon at least two traces corresponding to the first and the second electrode, respectively; and
d) at least one intermediate layer adapted to support the semiconductor die structure in a flip chip mounting manner on the traces of the submount, wherein the second electrode formed by multilayer coatings includes:
a transparent conducting layer formed on a top side of the second type semiconductor layer;
an ohmic contact layer formed on a partial surface of the transparent conducting layer;
a passivation layer enclosing the semiconductor die structure and a partial surface of the first electrode, but not covering the surface of the ohmic contact layer;
a highly reflective metal layer adhered to a top side of the ohmic contact layer;
a barrier layer for preventing the metallic diffusion, the barrier layer being formed on a top side of the high reflective metal layer; and
a bonding layer electrically coupled to the intermediate layer, the bonding layer being formed on a top side of the barrier layer.

16. The flip-chip electrode light-emitting element formed by multilayer coatings as recited in claim 15 wherein the passivation layer includes a silicon dioxide (SiO₂).

17. The flip-chip electrode light-emitting element formed by multilayer coatings as recited in claim 15 wherein the ohmic contact layer is formed in an evenly protruding manner.
